(19) United States
(12) Patent Application Publication
(10) Pub. No.: US 2006/0017103 A1
(43) Pub. Date: Jan. 26, 2006

(54) Method for making reduced size DMOS transistor and resulting DMOS transistor

(75) Inventor: Bertrand Szelag, Brie et Angonnes (FR)

Correspondence Address: FLEIT, KAIN, GIBBONS, GUTMAN, BONGINI;& BIANCO P.L., ONE BOCA COMMERCE CENTER, 551 NORTHWEST 77TH STREET, SUITE 111, BOCA RATON, FL, 33487, US

(73) Assignee: STMICROELECTRONICS SA, MONTROUGE (FR)

(21) Appl. No.: 11/146,306

(22) Filed: Jun. 6, 2005

(30) Foreign Application Priority Data
Jun. 7, 2004 (FR) 04 06092

(51) Int. Cl. H01L 29/78; H01L 21/336

(52) U.S. Cl. 257/335; 438/286

(57) ABSTRACT

A method is provided for making a laterally extended drain DMOS transistor. According to the method, a gate having two substantially parallel lateral faces is produced on a substrate, and a drain spacer and a source spacer made of an insulating material are produced on the lateral faces of the gate. The drain spacer and the source spacer are located on the drain side and the source side of the transistor, respectively. The width of the drain spacer is greater than a width of the source spacer. A DMOS transistor having such a gate and spacers is also provided. The width of the drain spacer is preferably substantially greater than the width of the source spacer, and is more preferably greater than the value of the absolute uncertainty relative to a dimension of a resin layer that is needed to perform a photolithography operation on the substrate.

### CROSS-REFERENCE TO RELATED APPLICATIONS

This application is based upon and claims priority from prior French Patent Application No. 04 06092, filed Jun. 7, 2004, the entire disclosure of which is herein incorporated by reference.

### FIELD OF THE INVENTION

The present invention relates to transistors, and more specifically to a method for manufacturing a laterally extended drain DMOS transistor and an associated DMOS transistor.

### BACKGROUND OF THE INVENTION

There is a well known manufacturing method for making a laterally extended drain DMOS transistor in which a gate having two substantially parallel lateral faces is deposited on a substrate, and then a drain spacer and a source spacer made of insulating material are defined on the lateral faces of the gate on the drain side and the source side of the transistor, respectively.

This manufacturing method can be used to make DMOS transistors of the type shown in FIG. 1. This transistor has a substantial distance between the drain and the gate (hence the term “lateral drain extension”) that enables it to withstand high voltages at its drain.

In greater detail, to make a DMOS transistor, first a polysilicon gate is formed on an appropriate type of silicon substrate by means of a photolithography step comprising the deposition of a layer of gate material such as polysilicon, and then the deposition of a layer of resin on this polysilicon layer. After the geometry of the gate has been defined by means of a mask, the resin is removed locally, and the polysilicon regions thus bared are etched so as to obtain the gate of the transistor after removal of the resin. The channel of the transistor is made by implanting dopants of an appropriate species, self-aligned with the gate on the source side. The zone to be implanted is defined by a photolithography step. The diffusion of the dopants beneath the gate defines the length of the channel.

Two spacers are then etched on either side of the gate using an insulating material. The insulating material used comprises, for example, a thin layer of silicon oxide coated with a nitride layer, with the oxide layer serving essentially as a barrier layer when the nitride is etched.

Spacers are well known for the manufacturing of transistors, particularly MOS transistors. Spacers are electrical isolation means, positioned symmetrically on either side of the gate. They are identical on the drain side and on the source side, and extend from a lateral face of the gate in the direction of the drain or the source. Their function is to prevent a short circuit between the gate and the drain or between the gate and the source during the formation of the silicide during the formation of the metallic electrical contacts of the transistor. Such spacers are for example described in U.S. Pat. No. 4,891,326.

An implanting step is then performed to form the drain and the source of the transistor on either side of the gate. To this end, a resin layer is deposited and then removed locally after a specific implantation masking to bare the zone of the substrate comprising the DMOS transistor. Then appropriate dopants are implanted in this zone so as to make implanted zones. On the source side, the dopants, which are implanted so as to be self-aligned with the gate, get diffused beneath this gate. On the drain side, the implanting is not done near the gate. The distance between the drain and the gate constitutes the DMOS extension that defines the behavior under voltage.

A metallizing step is then performed to make metal contacts that are designed to connect the drain, the gate and the source of the transistor to external circuits. This is achieved first by the deposition, through photolithography, of a protection layer (for example nitride) on the silicon of polysilicon conductive surfaces which should not be metallized, especially the region between the drain and the gate. Then, a metal compound (containing, for example, titanium, nickel or cobalt, i.e., a metal that reacts with silicon in the reaction of siliconization) is deposited on the bared regions, at the drain, the gate and the source, to form metal contacts.

An example of a transistor resulting from this method is shown in FIG. 1. The spacers 11 and 12 on either side of the gate 13 have a base width of about 0.1 μm. There is a distance of about 0.5 to 1 μm between the drain contact 15 and the polysilicon forming the gate 13, with this distance depending on the behavior under voltage that is required for the transistor. The gate contact 16, forming the active surface of the gate, has a width of about 0.3 μm, defined as a function of the desired properties of the gate 13. The polysilicon forming the gate, for its part, has a width of about 0.5 μm.

The protection layer 14, which is designed to prevent siliconizing in the undesired regions during the formation of the contacts 15, 16, and 17, stretches widely, covering the spacer 11 on the drain side and partly covering the polysilicon forming the gate 13. This is because of uncertainty with respect to the size of the resin layer that is needed to make the protection layer 14 in the appropriate zones by photolithography.

Indeed, as stated above, the step for metallizing the contacts is preceded by a photolithography step aimed at depositing a protection layer on the zones in which a metallization is likely to occur but is not desired, especially the region between the drain and the gate. This step for depositing the protection layer includes the deposition, on the entire surface of the circuit, of a layer of protection material (for example an insulating material such as nitride), and then the deposition of a layer of resin on the layer of protection material. After the definition, using a mask, of the geometry of the zones to be protected, the resin is removed locally and the thus bared regions of the layer of protection material are etched so that, after the removal of the resin, a protection layer 14 is obtained solely on the zones in which metallization is not required.

The defining of the zones to be protected thus entails the deposition/etching of a resin layer. The conventional methods used for a step of this type do not give precision of more than 0.2 μm in absolute width. Thus, to ensure that the entire silicon zone between the drain contact zone and the gate is effectively protected by a protection layer, it is necessary for this protection layer to extend by 0.2 μm beyond the desired limit. This layer 14 thus covers the spacer on the drain side and a part of the polysilicon gate over a width of about 0.2 μm. To obtain a gate contact 16 of about 0.3 μm, it is thus necessary to plan for a polysilicon gate 13 of about 0.5 μm, which produces a substantial increase in size.

Furthermore, the polysilicon zone covered by the protection layer induces parasitic capacitance between the gate and the drain of the transistor that impairs the dynamic performance of the transistor, especially its transition frequency.

### SUMMARY OF THE INVENTION

It is an object of the present invention to make a DMOS transistor that does not have these drawbacks.

Another object of the present invention is to provide a laterally extended drain DMOS transistor of reduced width with improved dynamic performance as compared with conventional DMOS transistors.

One embodiment of the present invention provides a method for making a laterally extended drain DMOS transistor. According to the method, a gate having two substantially parallel lateral faces is produced on a substrate, and a drain spacer and a source spacer made of an insulating material are produced on the lateral faces of the gate. The drain spacer is located on a drain side of the transistor and the source spacer is located on a source side of the transistor. The width of the drain spacer is greater than the width of the source spacer.

Another embodiment of the present invention provides a laterally extended drain DMOS transistor that includes a substrate, a gate located above the substrate, a drain spacer on a first lateral face of the gate, and a source spacer on a second lateral face of the gate. The drain spacer is located on the drain side of the gate, and the source spacer is located on the source side of the gate. The width of the drain spacer is greater than the width of the source spacer.

Other objects, features, and advantages of the present invention will become apparent from the following detailed description. It should be understood, however, that the detailed description and specific examples, while indicating preferred embodiments of the present invention, are given by way of illustration only and various modifications may naturally be performed without deviating from the present invention.

### BRIEF DESCRIPTION OF THE DRAWINGS

FIG. 1 is a view of a conventional DMOS transistor,

FIGS. 2a to 2g show the steps of a method according to a preferred embodiment of the present invention, and

FIG. 3 is a view of a transistor that is produced by the method of the preferred embodiment of the present invention.

### DETAILED DESCRIPTION OF PREFERRED EMBODIMENTS

Preferred embodiments of the present invention will be described in detail hereinbelow with reference to the attached drawings.

Preferred embodiments of the present invention provide methods in which a drain spacer is made with a width that is greater than that of the source spacer. Preferably, the drain spacer is made with a width that is greater than the value of the absolute uncertainty relative to a dimension of a resin layer that is needed to perform a photolithography operation. For example, in one exemplary embodiment the width of the source spacer is about 0.1 μm and the width of the drain spacer is about 0.2 to 0.3 μm.

With a drain spacer of this type, it is possible, before siliconization, to deposit a layer of protective resin between the drain and the gate which covers solely the zone between the drain and the gate and does not extend onto the gate itself. The gate contact made thereafter may thus cover the entire surface of the gate. With such embodiments of the present invention, it is thus possible to reduce the width of the gate. This enables a reduction in the overall width of the transistor.

In one embodiment, to make a drain spacer with a width that is greater than the width of the source spacer, the following process is performed. A primary drain spacer and a primary source spacer having the same width are deposited on the lateral faces of the gate. A secondary drain spacer and a secondary source spacer are deposited above the primary drain spacer and above the primary source spacer, respectively, so as to cover the primary drain spacer and the primary source spacer, and at least a portion of the secondary source spacer is removed.

The deposition of the primary spacers, the deposition of the secondary spacers and the removal of the secondary source spacer are preferably achieved by photolithography.

The present invention also provides transistors that are obtained according to such methods.

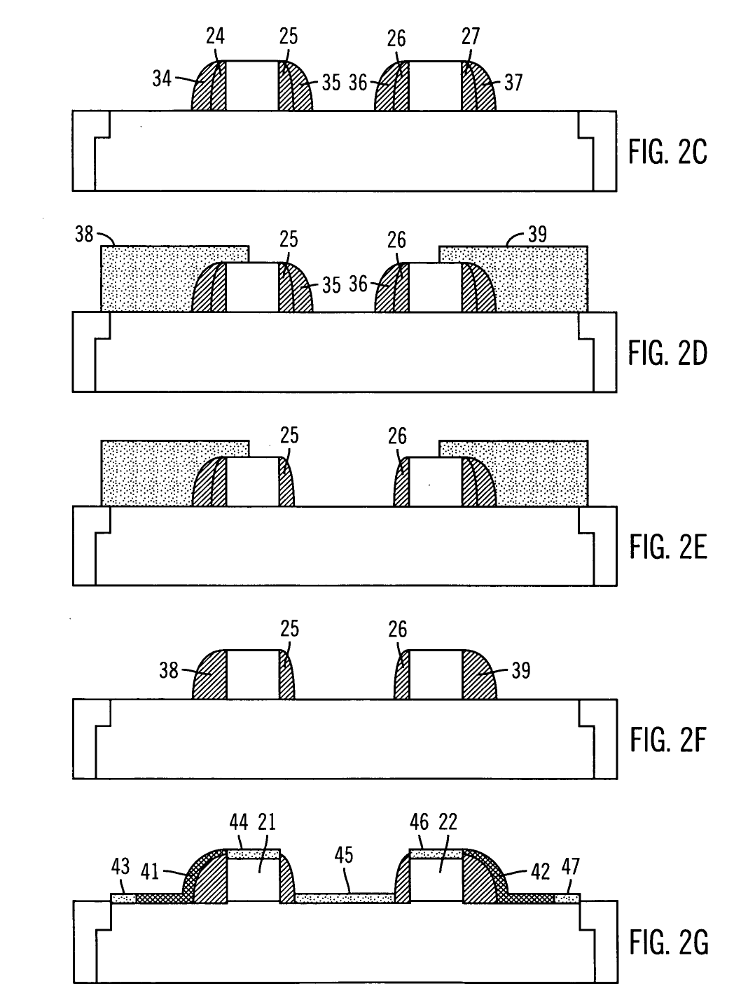

Exemplary embodiments of the present invention will now be described in detail with reference to FIGS. 2a to 3.

FIGS. 2a to 2g show the steps of a method for making two laterally extended DMOS transistors according to a preferred embodiment of the present invention.

To make transistors according to this method, gates 21 and 22 are made first on the silicon substrate by a known photolithography step. Primary spacers 24, 25, 26, and 27 are then made on both sides of the gates out of an insulating material. The primary spacers on the drain side and source side have substantially the same width (FIG. 2a).

According to this embodiment of the present invention, the primary spacers on the drain side 24 and 27 are then widened as follows.

A thin oxide layer is deposited on the substrate, the primary spacers and the gates, and then covered with a nitride layer 31 (FIG. 2b). The oxide layer and the nitride layer 31 together form a layer of insulating material, with the oxide layer being used as a barrier layer for the following etching step during which secondary spacers 34, 35, 36, and 37 (FIG. 2c) are formed above the primary spacers 24, 25, 26, and 27 in the nitride layer 31. Deposition of a nitride layer of a thickness sufficient to make spacers of the desired width is followed by the etching of the nitride to make the secondary spacers 34, 35, 36, and 37.

The secondary spacers 35 and 36 on the source side are then eliminated by photolithography. For this purpose a protective layer of resin is deposited on the secondary spacers on the drain side 34 and 37 (FIG. 2d), and the secondary spacers on the source side 35 and 36 are eliminated by etching the nitride which constitutes them (FIG. 2e). The resin is then removed (FIG. 2f).

Thus, for each transistor, a drain side spacer 38 or 39 (formed by a primary spacer covered by a secondary spacer) is obtained. This spacer is substantially wider than the source side spacer 25 or 26. The primary and secondary spacers do not necessarily have the same width. The width of the primary spacers is preferably chosen according to the same criteria as with conventional transistors, especially according to the distance required between the gate and the source. The width of the secondary spacers is preferably chosen so that the resulting width of the drain side spacers is greater than the value corresponding to the absolute uncertainty on the definition of the dimensions of a layer of resin that is subsequently used to make metal contacts. By way of example, in one embodiment the dimensions chosen for the source side spacers are on the order of 0.1 μm and those on the drain side spacers are on the order of 0.2 to 0.3 μm.

An appropriate conventional implantation step is then performed to form the drain and the source of the transistor on either side of the gate, such as according to the conventional method described above.

Then comes a metallization step to make metal contacts that are designed to connect the drain, the gate and the source of the transistor to the exterior. To this end, first, using photolithography, a protection layer 41 and 42 (for example nitride) is deposited on the conductive silicon and polysilicon surfaces which should not be metallized. The protection layer 41 and 42 covers the regions between the drain and the gate of each transistor, but does not encroach on the polysilicon gates 21 and 22. The contacts are then made as in the conventional process. A metal compound (such as titanium, nickel, or cobalt, i.e., a metal that reacts with silicon in the siliconizing reaction) is deposited on the bared regions at the drain, the gate and source to form metal contacts. After the contacts have been made, the resin is removed.

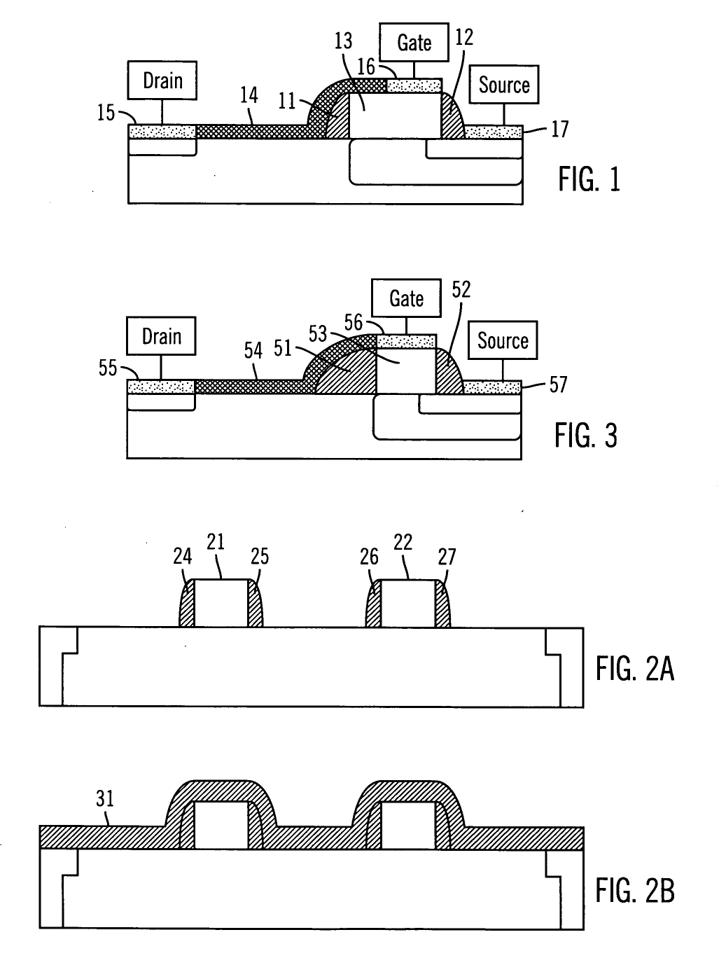

The transistor resulting from the above-described method is shown in FIG. 3. As compared with the conventional DMOS transistor of FIG. 1, the main characteristics of the DMOS transistor of FIG. 3 are the following.

The drain spacer 51 is substantially bigger than its source spacer 52, with the width of the drain spacer preferably being chosen to be greater than the value corresponding to the absolute uncertainty on the sizing of a resin layer that is used in the context of a photolithography operation. By way of an example, in one exemplary embodiment the width of the source spacer is on the order of 0.1 μm and the width of the drain spacer is on the order of 0.2 to 0.3 μm.

The gate contact 56 has a width that is substantially the same as the width of the polysilicon gate 53 which it covers. Preferably, the size of the gate is reduced to the desired width of overlapping by the gate contact giving a gain of 10 to 20% on the width of the transistor; thus, a transistor with good dynamic performance is obtained.

Despite the use of a drain spacer that is wider than the source spacer, the distance between the drain and the gate preferably remains unchanged and depends solely on the behavior under voltage that is required for the transistor.

The drain or source spacer and the protection layer 41 and 42 may be made out of the same insulating material, formed for example by a deposited thin oxide layer and a nitride layer.

While there has been illustrated and described what are presently considered to be the preferred embodiments of the present invention, it will be understood by those skilled in the art that various other modifications may be made, and equivalents may be substituted, without departing from the true scope of the present invention. Additionally, many modifications may be made to adapt a particular situation to the teachings of the present invention without departing from the central inventive concept described herein. Furthermore, an embodiment of the present invention may not include all of the features described above. Therefore, it is intended that the present invention not be limited to the particular embodiments disclosed, but that the invention include all embodiments falling within the scope of the appended claims.

What is claimed is:

1. A method for making a laterally extended drain DMOS transistor having a drain and a source, said method comprising the steps of:
producing a gate on a substrate, the gate having two substantially parallel lateral faces; and
producing a drain spacer and a source spacer made of an insulating material on the lateral faces of the gate, the drain spacer being located on a drain side of the transistor and the source spacer being located on a source side of the transistor,
wherein a width of the drain spacer is greater than a width of the source spacer.

2. The method according to claim 1, wherein the width of the drain spacer is greater than a value of the absolute uncertainty relative to a dimension of a resin layer that is needed to perform a photolithography operation on the substrate.

3. The method according to claim 1, wherein the width of the source spacer is about 0.1 μm and the width of the drain spacer is about 0.2 to 0.3 μm.

4. The method according to claim 1, wherein the width of the drain spacer is at least two times the width of the source spacer.

5. The method according to claim 1, wherein the step of producing the drain spacer and the source spacer comprises the sub-steps of:
depositing a primary drain spacer and a primary source spacer on the lateral faces of the gate, the primary drain spacer and the primary source spacer having substantially the same width;
depositing a secondary drain spacer on the primary drain spacer and a secondary source spacer on the primary source spacer; and
removing at least a portion of the secondary source spacer.

6. The method according to claim 5, wherein the sub-steps of depositing the primary spacers, depositing the secondary spacers, and removing the secondary source spacer are achieved using photolithography.

7. The method according to claim 1, further comprising the step of producing a gate contact on the gate, the gate contact having a width that is substantially equal to the width of the gate.

8. The method according to claim 7, wherein the step of producing the gate contact comprises the sub-steps of:
depositing a protection layer on the drain spacer and on the substrate between the drain spacer and the drain; and
siliconizing a portion of the transistor that is not covered by the protection layer to form the gate contact.

9. A laterally extended drain DMOS transistor comprising:
a substrate;
a gate located above the substrate;
a drain spacer on a first lateral face of the gate, the drain spacer being located on the drain side of the gate; and
a source spacer on a second lateral face of the gate, the source spacer being located on the source side of the gate,
wherein a width of the drain spacer is greater than a width of the source spacer.

10. The DMOS transistor according to claim 9, wherein the width of the drain spacer is greater than a value of the absolute uncertainty relative to a dimension of a resin layer that is needed to perform a photolithography operation on the substrate.

11. The DMOS transistor according to claim 9, wherein the width of the drain spacer is from about two to about three times the width of the source spacer.

12. The DMOS transistor according to claim 9, wherein the width of the drain spacer is at least two times the width of the source spacer.

13. The DMOS transistor according to claim 9, further comprising a protection layer located over the drain spacer and over the substrate between the drain spacer and the drain.

14. The DMOS transistor according to claim 13, wherein the protection layer is not located over the gate.

15. The DMOS transistor according to claim 9, further comprising a gate contact above the gate, the gate contact having a width that is substantially equal to the width of the gate.

16. An integrated circuit including at least one laterally extended drain DMOS transistor that comprises:
a substrate;
a gate located above the substrate;
a drain spacer on a first lateral face of the gate, the drain spacer being located on the drain side of the gate; and
a source spacer on a second lateral face of the gate, the source spacer being located on the source side of the gate,
wherein a width of the drain spacer is greater than a width of the source spacer.

17. The integrated circuit according to claim 16, wherein the width of the drain spacer of the DMOS transistor is greater than a value of the absolute uncertainty relative to a dimension of a resin layer that is needed to perform a photolithography operation on the substrate.

18. The integrated circuit according to claim 16, wherein the width of the drain spacer of the DMOS transistor is at least two times the width of the source spacer.

19. The integrated circuit according to claim 16, wherein the DMOS transistor further comprises a protection layer located over the drain spacer and over the substrate between the drain spacer and the drain.

20. The integrated circuit according to claim 16, wherein the DMOS transistor further comprises a gate contact above the gate, the gate contact having a width that is substantially equal to the width of the gate.
